(19) United States
(12) Patent Application Publication
(10) Pub. No.: US 2013/0161666 A1
(43) Pub. Date: Jun. 27, 2013

(54) DIRECTLY PATTERNED LATERAL HYBRID COLOR OLED ARRAYS SYSTEM AND METHOD

(71) Applicants: Amalkumar P. Ghosh, Beacon, NY (US); Ilyas Khayfullin, Hopewell Junction, NY (US); Tariq Ali, Hopwell Junction, NY (US)

(72) Inventors: Amalkumar P. Ghosh, Beacon, NY (US); Ilyas Khayfullin, Hopewell Junction, NY (US); Tariq Ali, Hopwell Junction, NY (US)

(21) Appl. No.: 13/332,842

(22) Filed: Dec. 21, 2011

(51) Int. Cl. H01L 51/50; H01L 33/08

(52) U.S. Cl. 257/89; 257/E33.061; 257/E51.018

(57) ABSTRACT

A display situated on a substrate surface is provided. The display includes a first light emitting sub-pixel situated on the substrate surface. The first light-emissive layer includes fluorescent material. The display also includes a second light emitting sub-pixel situated on the substrate surface. The second light-emissive layer includes phosphorescent material. The first light emitting sub-pixel and the second light emitting sub-pixel may be arranged proximate to each other on the substrate surface. The first light emitting sub-pixel and the second light emitting sub-pixel may be arranged laterally adjacent to each other on the substrate surface. A display situated on a substrate is provided first and second light-emissive layers interposed between a first base electrode and a first transparent electrode. The first light emitting sub-pixel further includes a first interlayer interposed between the first and second light-emissive layers.

### CROSS-REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

1. Field of the Invention

The present invention relates to organic light emitting diode (“OLED”) devices. In particular, the present invention relates to an OLED array utilizing both phosphorescent and fluorescent sub-pixels arranged laterally, and tandem fluorescent and/or phosphorescent sub-pixels.

2. Description of Prior Art

An OLED device typically includes a stack of thin layers formed on a substrate. In the stack, a light-emitting layer of a luminescent organic solid, as well as adjacent semiconductor layers, is sandwiched between a cathode and an anode. The light-emitting layer may be selected from any of a multitude of fluorescent and/or phosphorescent organic solids. Any of the layers, and particularly the light-emitting layer, may consist of multiple sub layers.

In a typical OLED, either the cathode or the anode is transparent. The films may be formed by evaporation, spin casting, other appropriate polymer film-forming techniques, or chemical self-assembly. Thicknesses typically range from a few monolayers to about 1 to 2,000 angstroms. Protection of OLED against oxygen and moisture can be achieved by encapsulation of the device. The encapsulation can be obtained by means of a single thin-film layer situated on the substrate, surrounding the OLED.

High resolution active matrix displays may include millions of pixels and sub-pixels that are individually addressed by the drive electronics. Each sub-pixel can have several semiconductor transistors and other IC components. Each OLED may correspond to a pixel or a sub-pixel, and these terms are used interchangeably herein.

Phosphorescent OLEDs may have higher efficiency than fluorescent OLEDs, and in particular may operate at current having one tenth the magnitude as may be used for a fluorescent OLED. Stacked hybrid OLEDs may utilize both fluorescent and phosphorescent OLEDs in a stack to create white light. This light may be filtered to create any possible light color.

### BRIEF SUMMARY OF THE INVENTION

The present invention provides a display able to deliver very high efficiency OLED displays having a very long operational lifetime. Additionally or alternatively, the present invention enables manufacturing of ultra-high resolution micro-displays with better control of the emitted light spectra.

A display situated on a substrate surface is provided. The display includes a first light emitting sub-pixel situated on the substrate surface and including a first base electrode, a first transparent electrode, and a first light-emissive layer interposed between the first base electrode and the first transparent electrode. The first light-emissive layer includes fluorescent material. The display also includes a second light emitting sub-pixel situated on the substrate surface and including a second base electrode, a second transparent electrode, and a second light-emissive layer interposed between the second base electrode and the second transparent electrode. The second light-emissive layer includes phosphorescent material.

The second light emitting sub-pixel may have a greater efficiency than the first light emitting sub-pixel. The first light emitting sub-pixel and the second light emitting sub-pixel may be arranged proximate to each other on the substrate surface. The first light emitting sub-pixel and the second light emitting sub-pixel may be arranged laterally adjacent to each other on the substrate surface.

The first light-emissive layer may be adapted to emit blue light, and the second light-emissive layer may be adapted to emit one of red light and green light.

The display may include a third light emitting sub-pixel situated on the substrate surface and including a third base electrode, a third transparent electrode, and a third light-emissive layer interposed between the third base electrode and the third transparent electrode. The third light-emissive layer may include phosphorescent material. The second light-emissive layer may be adapted to emit red light, and the third light-emissive layer may be adapted to emit green light.

The first light emitting sub-pixel, the second light emitting sub-pixel, and the third light emitting sub-pixel may be arranged proximate to each other on the substrate surface. The first light emitting sub-pixel, the second light emitting sub-pixel, and the third light emitting sub-pixel may be arranged laterally adjacent to each other on the substrate surface. The first, second, and third light emitting sub-pixels may form a color pixel.

A color display situated on a substrate surface is provided. The color display includes a first light emitting sub-pixel situated on the substrate surface and including a first base electrode, a first transparent electrode, and a first light-emissive layer interposed between the first base electrode and the first transparent electrode. The first light-emissive layer includes fluorescent material and is adapted to emit blue light. The color display also includes a second light emitting sub-pixel situated on the substrate surface and including a second base electrode, a second transparent electrode, and a second light-emissive layer interposed between the second base electrode and the second transparent electrode. The second light-emissive layer includes phosphorescent material and is adapted to emit red light. The color display also includes a third light emitting sub-pixel situated on the substrate surface and including a third base electrode, a third transparent electrode, and a third light-emissive layer interposed between the third base electrode and the third transparent electrode. The third light-emissive layer includes phosphorescent material and is adapted to emit green light.

The second and third light emitting sub-pixels may have a greater efficiency than the first light emitting sub-pixel. The first light emitting sub-pixel, the second light emitting sub-pixel, and the third light emitting sub-pixel may be arranged proximate to each other on the substrate surface. The first light emitting sub-pixel, the second light emitting sub-pixel, and the third light emitting sub-pixel may be arranged laterally adjacent to each other on the substrate surface.

A display situated on a substrate is provided. The display includes a first light emitting sub-pixel situated on the substrate surface that includes a first base electrode, a first transparent electrode, and first and second light-emissive layers interposed between the first base electrode and the first transparent electrode. The first light emitting sub-pixel further includes a first interlayer interposed between the first and second light-emissive layers. The first and second light-emissive layers are each adapted to emit light of a first color. The display further includes a second light emitting sub-pixel situated on the substrate surface that includes a second base electrode, a second transparent electrode, and third and fourth light-emissive layers interposed between the second base electrode and the second transparent electrode. The second light emitting sub-pixel further includes a second interlayer interposed between the third and fourth light-emissive layers. The third and fourth light-emissive layers are each adapted to emit light of a second color, and the second color is different than the first color.

The second light emitting sub-pixel may have a greater efficiency than the first light emitting sub-pixel. The first light emitting sub-pixel and the second light emitting sub-pixel may be arranged proximate to each other on the substrate surface. The first light emitting sub-pixel and the second light emitting sub-pixel may be arranged laterally adjacent to each other on the substrate surface. The first light-emissive layer may be adapted to emit blue light, and the second light-emissive layer may be adapted to emit red light or green light.

The display may include a third light emitting sub-pixel situated on the substrate surface that includes a third base electrode, a third transparent electrode, and fifth and sixth light-emissive layers interposed between the third base electrode and the third transparent electrode. The third light emitting sub-pixel may include a third interlayer interposed between the fifth and sixth light-emissive layers, and the fifth and sixth light-emissive layers may each be adapted to emit light of a third color. The third color may be different than the first color and the second color. The second light-emissive layer may be adapted to emit red light, and the third light-emissive layer may be adapted to emit green light.

The first light emitting sub-pixel, the second light emitting sub-pixel, and the third light emitting sub-pixel may be arranged proximate to each other on the substrate surface. The first light emitting sub-pixel, the second light emitting sub-pixel, and the third light emitting sub-pixel may be arranged laterally adjacent to each other on the substrate surface.

These objects and the details of the invention will be apparent from the following description and accompanying drawings.

### BRIEF DESCRIPTION OF THE DRAWINGS

FIG. 1 is a perspective view of an OLED array in accordance with an exemplary embodiment;

FIG. 2 is a side view of a conventional hybrid OLED stack;

FIG. 3 is a perspective view of an OLED array in accordance with another exemplary embodiment;

FIG. 4 is a perspective view of an OLED array in accordance with another exemplary embodiment;

FIG. 5 is a perspective view of an OLED array in accordance with another exemplary embodiment;

FIG. 6 illustrates a method according to an exemplary embodiment; and

FIG. 7 illustrates a computer system according to an exemplary embodiment.

### DETAILED DESCRIPTION OF THE INVENTION

The present invention relates to an OLED display, and in particular relates to a structure, material composition and arrangement of red, green and blue sub-pixels and method of manufacturing of an OLED display. The present invention proposes several related concepts of Lateral Hybrid OLED (LH-OLED) display, Lateral Hybrid Tandem OLED (LHT-OLED) display, Lateral Tandem Fluorescent (LTF-OLED) display, and Lateral Tandem Phosphorescent (LTP-OLED) display.

Phosphorescent emissive layers typically require only low current and/or low voltage to emit significant amounts of light. In contrast, fluorescent emissive layers typically require higher current and/or higher voltage to emit significant amounts of light. In this manner, displays based on pixels and/or sub-pixels having phosphorescent emissive layers are generally considered more efficient, and may also have a longer operational lifetime. Red and green phosphorescent materials have been used in color displays for this reason. Blue phosphorescent material is considered more difficult to produce and/or use in a display, and therefore sometimes blue fluorescent material is used even when phosphorescent red and green material is being used in a display.

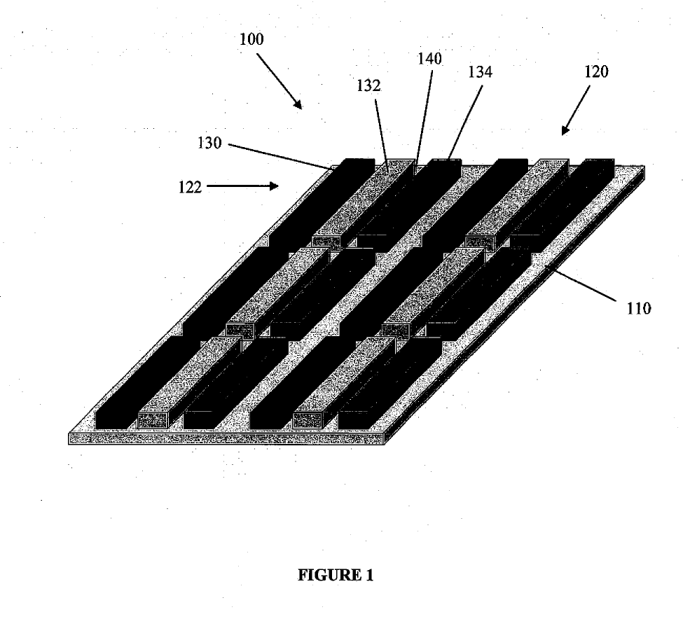

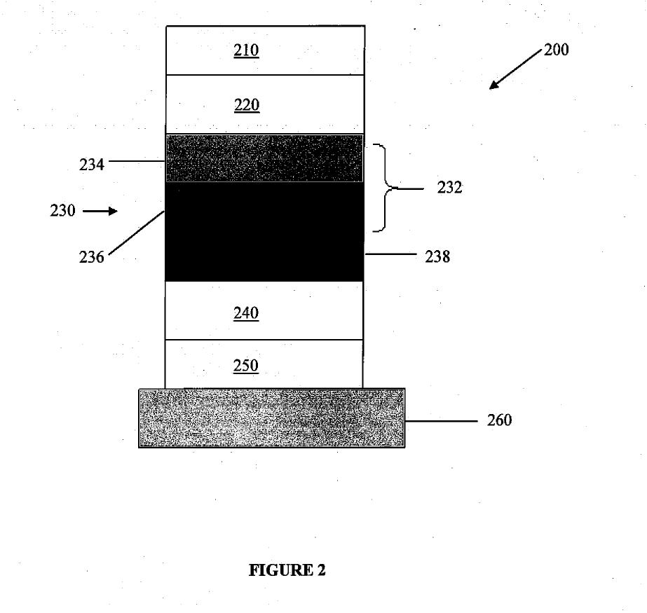

The conventional hybrid OLED consists of a vertical stack of OLED layers that are placed in series on top of each other as shown in FIG. 2. Such a stack has the inherent disadvantage that it incorporates a fluorescent layer and phosphorescent layer(s) in series. Since the current density required to operate a fluorescent OLED is almost an order of magnitude higher than necessary to operate a phosphorescent OLED to get the same level of brightness, such a scheme is inherently limited in both efficiency and operational lifetime of the devices. The present invention avoids this limitation by incorporating the fluorescent and the phosphorescent OLED sub-pixels side-by-side to form a pixel, as shown in FIG. 1. Such a structure (referred to herein as a Lateral Hybrid OLED display) enables the system to drive the fluorescent and the phosphorescent OLEDs separately so that the lifetime, brightness, and the overall emission spectrum of the OLED display may be significantly improved.

In addition, such a Lateral Hybrid OLED display may be fabricated using the technique of Thermal Dye Transfer (TDT). Such a method may allow the patterning of ultra-high resolution micro-displays with Lateral Hybrid structure.

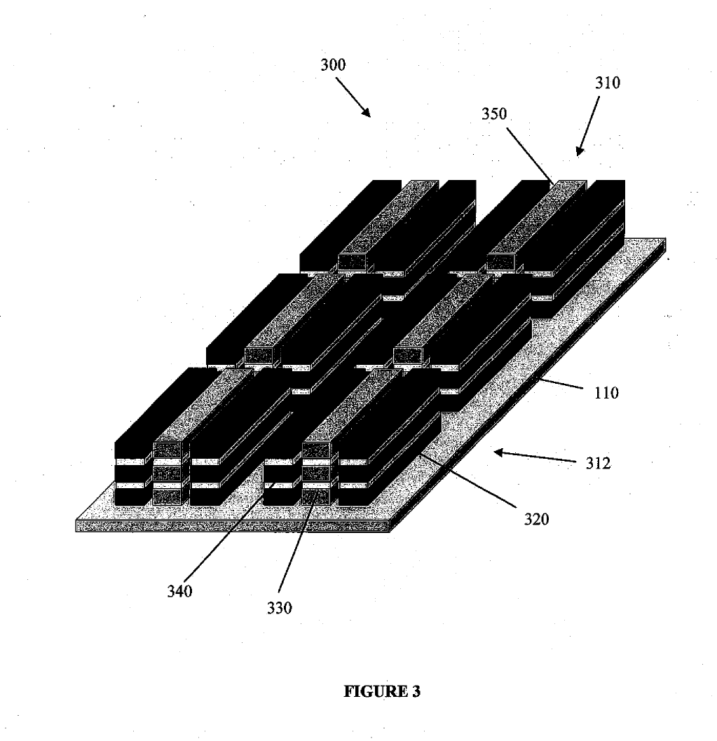

Further, using the TDT method and the concept of a Lateral Hybrid structure, a tandem OLED can be fabricated which provides a Lateral Hybrid Tandem OLED (LHT-OLED) display, as shown in FIG. 3. Such a device may provide the following significant benefits: 1) high efficiency; 2) long lifetime; 3) high control of emitted light spectra; and 4) patterning of ultra-high resolution displays.

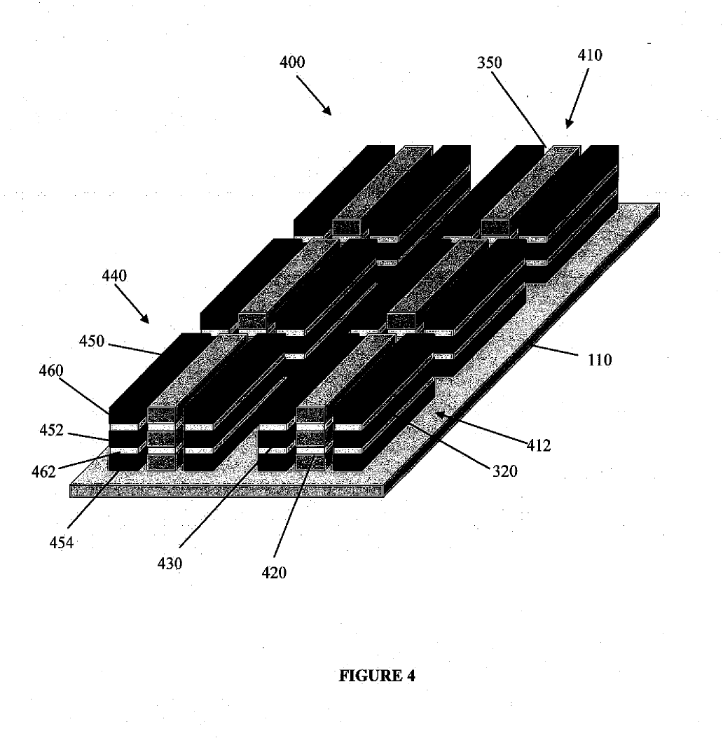

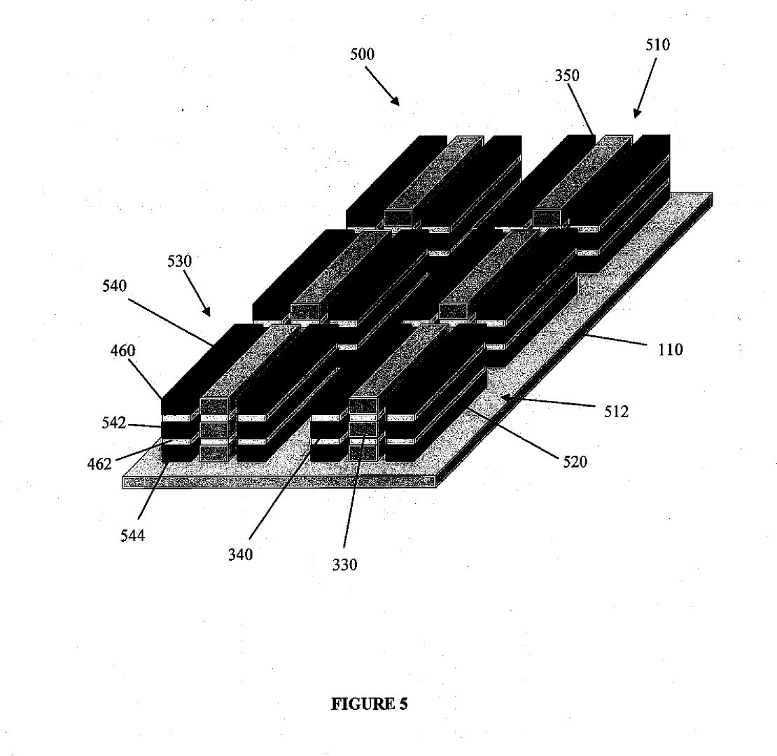

Furthermore, lateral tandem OLED can be fabricated using either fluorescent (LTF-OLED) or phosphorescent (LTP-OLED) materials, as shown in FIGS. 4 and 5 respectively, and may be made by any method, including but not limited to TDT.

FIG. 1 is a perspective view of OLED array 100 in accordance with an exemplary embodiment. OLED array 100 of FIG. 1 is a Lateral hybrid OLED (LH-OLED) array, and may be a color display or a portion of a color display. OLED array 100 includes pixels 120, 122 mounted on substrate 110. Substrate 110 may be formed of any appropriate material, and may for instance be a silicon wafer. Pixel 122 may include three sub-pixels 130, 132, 134 of different colors, and in particular may include a red sub-pixel, a green sub-pixel, and a blue sub-pixel. One or two of the sub-pixels of pixel 122 may be fluorescent sub-pixel(s), in which the emissive layer in the sub-pixel is a fluorescent material. The other sub-pixels of pixel 122 may be phosphorescent sub-pixel(s), in which the emissive layer in the sub-pixel is a phosphorescent material. In one exemplary embodiment of pixel 122, sub-pixel 130 may be a phosphorescent red sub-pixel, sub-pixel 132 may be a phosphorescent green sub-pixel, and sub-pixel 134 may be a fluorescent blue sub-pixel. Gap 140 between sub-pixels 132 and 134 may be a small space or air gap, on the order of 1 micrometer. Alternatively, gap 140 may be filled with a black matrix material to prevent optical cross-talk between sub-pixels 132 and 134. In still other embodiments, there may be no gap 140 between sub-pixels 132 and 134, which may then be tightly packed together. A similar gap 140 may exist between other adjacent sub-pixels of the same pixel, and/or other adjacent sub-pixels of adjacent pixels.

FIG. 2 illustrates conventional hybrid OLED 200, which is a stacked OLED, in a side view. Conventional hybrid OLED 200 has top layer 210 on a side away from the substrate, which may be a cathode. Top layer 210 may be transparent, or may include a color filter. Alternatively, top layer 210 may be an anode. Under top layer 210 is electron transport layer (ETL) 220, which may operation to facilitate the transport of electrons into the emissive layers. Under ETL 220 are emissive layers 230, which may include phosphorescent emissive layers 232 and fluorescent emissive layers 238. In particular, emissive layers 230 may include phosphorescent green layer 234, phosphorescent red layer 236, and fluorescent blue layer 238. Under fluorescent blue layer 238 may be hole transport layer 240, which may operate to facilitate the transport of positive electrical charge, also referred to herein as holes. Under fluorescent blue layer 238 may be bottom layer 250, which may be an anode or in an alternative configuration may be a cathode. Bottom layer 250, and consequently all of conventional hybrid OLED 200, may be mounted on substrate 260, which may be a silicon wafer.

FIG. 3 is a perspective view of lateral hybrid tandem OLED (LHT-OLED) array 300 with phosphorescent red and green and fluorescent blue sub-pixels in accordance with an exemplary embodiment. LHT-OLED array 300 of FIG. 3 may be a color display or a portion of a color display. LHT-OLED array 300 includes pixels 310, 312 mounted on substrate 110. Pixel 312 may include three sub-pixels 320, 330, 340 of different colors, and in particular may include a red sub-pixel, a green sub-pixel, and a blue sub-pixel. One or two of the sub-pixels of pixel 312 may be fluorescent sub-pixel(s), in which the emissive layers in the sub-pixel(s) include a fluorescent material. The other sub-pixels of pixel 312 may be phosphorescent sub-pixel(s), in which the emissive layers in the sub-pixel(s) include a phosphorescent material. In one exemplary embodiment of pixel 312, sub-pixel 320 may be a fluorescent blue sub-pixel, sub-pixel 330 may be a phosphorescent green sub-pixel, and sub-pixel 340 may be a phosphorescent red sub-pixel. Each of sub-pixel 320, sub-pixel 330, and sub-pixel 340 may include distinct and separate emissive layers, which may be identical and/or separated by a tandem interlayer. The separate emissive layers may be adapted to emit light having a similar or identical emissive spectra. In this manner, sub-pixel 320, sub-pixel 330, and sub-pixel 340 may be adapted to have a brighter output than a sub-pixel having only a single emissive layer.

Gap 350 between sub-pixels of pixel 310 may be a small space or air gap, on the order of 1 micrometer. Alternatively, gap 350 may be filled with a black matrix material to prevent optical cross-talk between sub-pixels of pixel 310. In still other embodiments, there may be no gap 350 between sub-pixels of pixel 310, which may then be tightly packed together. A similar gap 350 may exist between other adjacent sub-pixels of the same pixel, and/or other adjacent sub-pixels of adjacent pixels.

FIG. 4 is a perspective view of lateral tandem OLED (LTF-OLED) array 400 with all fluorescent red, green and blue sub-pixels in accordance with an exemplary embodiment. LTF-OLED array 400 of FIG. 4 may be a color display or a portion of a color display. LTF-OLED array 400 includes pixels 410, 412 mounted on substrate 110. Pixel 412 may include three sub-pixels 320, 420, 430 of different colors, and in particular may include a red sub-pixel, a green sub-pixel, and a blue sub-pixel. All of the sub-pixels of pixel 412 may be fluorescent sub-pixels, in which the emissive layers in each sub-pixel include a fluorescent material. In one exemplary embodiment of pixel 412, sub-pixel 320 may be a fluorescent blue sub-pixel, sub-pixel 420 may be a fluorescent green sub-pixel, and sub-pixel 430 may be a fluorescent red sub-pixel. Each of sub-pixel 320, sub-pixel 420, and sub-pixel 430 may include distinct and separate emissive layers, which may be identical and/or separated by a tandem interlayer. Sub-pixel 440 in LTF-OLED array 400 may be a fluorescent red sub-pixel. Sub-pixel 440 may include three emissive layers 450, 452, 454. Alternatively, sub-pixel 440 may include more or fewer emissive layers. Each emissive layer is separated from an adjacent emissive layer by an interlayer. In particular, emissive layers 450 and 452 are separated by interlayer 460, and emissive layers 452 and 454 are separated by interlayer 462. Interlayers 460 and 462 may include many sub-layers, and in particular may include drive circuitry including anode and cathode sub-layers for driving electrons and/or holes to or through an emissive layer in order to generate a light output. Emissive layers 450, 452, 454 may be adapted to emit light having a similar or identical emissive spectra. In this manner, a sub-pixel having multiple emissive layers may have a brighter output than a sub-pixel having only a single emissive layer.

Gap 350 between sub-pixels of pixel 410 may be a small space or air gap, on the order of 1 micrometer. Alternatively, gap 350 may be filled with a black matrix material to prevent optical cross-talk between sub-pixels of pixel 410. In still other embodiments, there may be no gap 350 between sub-pixels of pixel 410, which may then be tightly packed together. A similar gap 350 may exist between other adjacent sub-pixels of the same pixel, and/or other adjacent sub-pixels of adjacent pixels.

FIG. 5 is a perspective view of lateral tandem OLED (LTP-OLED) array 500 with all phosphorescent red, green and blue sub-pixels in accordance with an exemplary embodiment. LTP-OLED array 500 of FIG. 5 may be a color display or a portion of a color display. LTP-OLED array 500 includes pixels 510, 512 mounted on substrate 110. Pixel 512 may include three sub-pixels 520, 330, 340 of different colors, and in particular may include a red sub-pixel, a green sub-pixel, and a blue sub-pixel. All of the sub-pixels of pixel 512 may be phosphorescent sub-pixels, in which the emissive layers in each sub-pixel include a phosphorescent material. In one exemplary embodiment of pixel 512, sub-pixel 520 may be a phosphorescent blue sub-pixel, sub-pixel 330 may be a phosphorescent green sub-pixel, and sub-pixel 340 may be a phosphorescent red sub-pixel. Each of sub-pixel 520, sub-pixel 330, and sub-pixel 340 may include distinct and separate emissive layers, which may be identical and/or separated by a tandem interlayer. Sub-pixel 530 in LTP-OLED array 500 may be a phosphorescent red sub-pixel. Sub-pixel 530 may include three emissive layers 540, 542, 544. Alternatively, sub-pixel 530 may include more or fewer emissive layers. Each emissive layer is separated from an adjacent emissive layer by an interlayer. In particular, emissive layers 540 and 542 are separated by interlayer 460, and emissive layers 542 and 544 are separated by interlayer 462. Interlayers 460 and 462 may include many sub-layers, and in particular may include drive circuitry including anode and cathode sub-layers for driving electrons and/or holes to or through an emissive layer in order to generate a light output. Emissive layers 540, 542, 544 may be adapted to emit light having a similar or identical emissive spectra. In this manner, a sub-pixel having multiple emissive layers may have a brighter output than a sub-pixel having only a single emissive layer.

Gap 350 between sub-pixels of pixel 510 may be a small space or air gap, on the order of 1 micrometer. Alternatively, gap 350 may be filled with a black matrix material to prevent optical cross-talk between sub-pixels of pixel 510. In still other embodiments, there may be no gap 350 between sub-pixels of pixel 510, which may then be tightly packed together. A similar gap 350 may exist between other adjacent sub-pixels of the same pixel, and/or other adjacent sub-pixels of adjacent pixels.

The interlayer discussed above and shown in FIGS. 4, 5, and 6 may include anodes, cathodes and drive circuitry for independently driving the emissive layers on either side of the interlayer. Additionally, the interlayer may include an electron transport layer, a hole transport layer, an electron blocking or barrier layer, and/or a hole blocking or barrier layer. The bottom side of each sub-pixel, adjacent to or integrated with the substrate, may additionally include anodes, cathodes and drive circuitry. A top side of each sub-pixel, on a face opposite the substrate, may include anodes, cathodes and drive circuitry, as well as a filter layer that may be used to tune, enhance, or adjust the emissive spectra of the particular sub-pixel in order to balance the color of the light emitted from the sub-pixel or the pixel when two or more sub-pixels are illuminated.

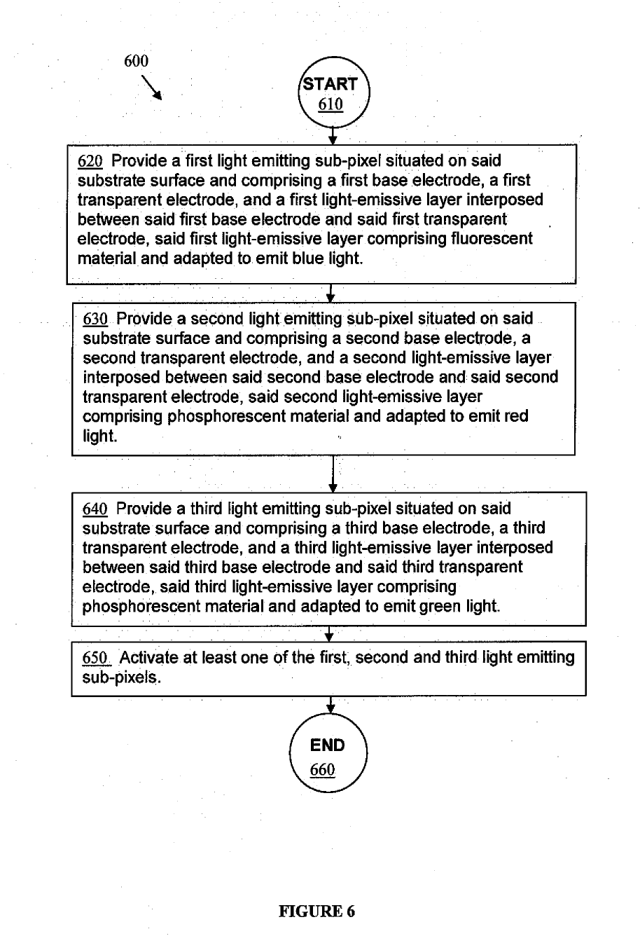

FIG. 6 illustrates method 600 according to an exemplary embodiment. Method 600 starts at start circle 610 and proceeds to operation 620, which indicates to provide a first light emitting sub-pixel situated on the substrate surface. The first light emitting sub-pixel includes a first base electrode, a first transparent electrode, and a first light-emissive layer interposed between the first base electrode and the first transparent electrode. The first light-emissive layer includes fluorescent material and is adapted to emit blue light. From operation 620, the flow in method 600 proceeds to operation 630, which indicates to provide a second light emitting sub-pixel situated on the substrate surface. The second light emitting sub-pixel includes a second base electrode, a second transparent electrode, and a second light-emissive layer interposed between the second base electrode and the second transparent electrode. The second light-emissive layer includes phosphorescent material and is adapted to emit red light. From operation 630, the flow in method 600 proceeds to operation 640, which indicates to provide a third light emitting sub-pixel situated on the substrate surface. The third light emitting sub-pixel includes a third base electrode, a third transparent electrode, and a third light-emissive layer interposed between the third base electrode and the third transparent electrode. The third light-emissive layer includes phosphorescent material and is adapted to emit green light. From operation 640, the flow in method 600 proceeds to operation 650, which indicates to activate at least one of the first, second and third light emitting sub-pixels. From operation 650, the flow in method 600 proceeds to end circle 660.

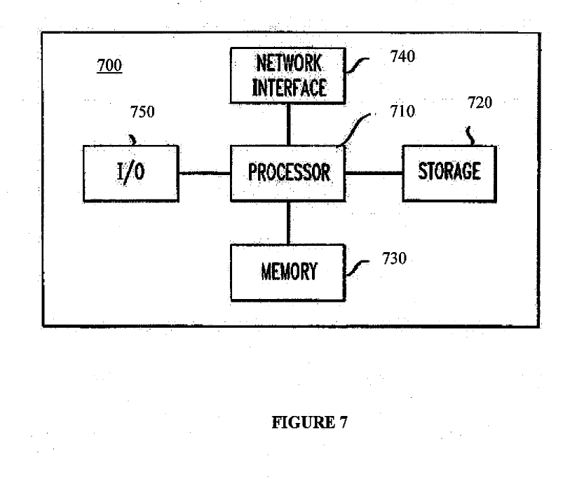

FIG. 7 illustrates a computer system according to an exemplary embodiment. Computer 700 can, for example, display 100, display 200, display 300, display 400, or display 500. Additionally, computer 700 can perform the steps described above (e.g., with respect to FIG. 6). Computer 700 contains processor 710 which controls the operation of computer 700 by executing computer program instructions which define such operation, and which may be stored on a computer-readable recording medium. The computer program instructions may be stored in storage 720 (e.g., a magnetic disk, a database) and loaded into memory 730 when execution of the computer program instructions is desired. Thus, the computer operation will be defined by computer program instructions stored in memory 730 and/or storage 720 and computer 700 will be controlled by processor 710 executing the computer program instructions. Computer 700 also includes one or more network interfaces 740 for communicating with other devices, for example other computers, servers, or websites. Network interface 740 may, for example, be a local network, a wireless network, an intranet, or the Internet. Computer 700 also includes input/output 750, which represents devices which allow for user interaction with the computer 700 (e.g., display, keyboard, mouse, speakers, buttons, webcams, etc.). One skilled in the art will recognize that an implementation of an actual computer will contain other components as well, and that FIG. 7 is a high level representation of some of the components of such a computer for illustrative purposes.

While only a limited number of preferred embodiments of the present invention have been disclosed for purposes of illustration, it is obvious that many modifications and variations could be made thereto. It is intended to cover all of those modifications and variations which fall within the scope of the present invention, as defined by the following claims.

We claim:

1. A display situated on a substrate surface, said display comprising:
a first light emitting sub-pixel situated on said substrate surface and comprising a first base electrode, a first transparent electrode, and a first light-emissive layer interposed between said first base electrode and said first transparent electrode, said first light-emissive layer comprising fluorescent material; and
a second light emitting sub-pixel situated on said substrate surface and comprising a second base electrode, a second transparent electrode, and a second light-emissive layer interposed between said second base electrode and said second transparent electrode, said second light-emissive layer comprising phosphorescent material.

2. The display of claim 1, wherein said second light emitting sub-pixel has a greater efficiency than said first light emitting sub-pixel.

3. The display of claim 1, wherein said first light emitting sub-pixel and said second light emitting sub-pixel are arranged proximate to each other on said substrate surface.

4. The display of claim 1, wherein said first light emitting sub-pixel and said second light emitting sub-pixel are arranged laterally adjacent to each other on said substrate surface.

5. The display of claim 1, wherein:
said first light-emissive layer is adapted to emit blue light; and
said second light-emissive layer is adapted to emit one of red light and green light.

6. The display of claim 5, further comprising:
a third light emitting sub-pixel situated on said substrate surface and comprising a third base electrode, a third transparent electrode, and a third light-emissive layer interposed between said third base electrode and said third transparent electrode, and said third light-emissive layer comprising phosphorescent material;
wherein said second light-emissive layer is adapted to emit red light; and
wherein said third light-emissive layer is adapted to emit green light.

7. The display of claim 6, wherein said first light emitting sub-pixel, said second light emitting sub-pixel, and said third light emitting sub-pixel are arranged proximate to each other on said substrate surface.

8. The display of claim 6, wherein said first light emitting sub-pixel, said second light emitting sub-pixel, and said third light emitting sub-pixel are arranged laterally adjacent to each other on said substrate surface.

9. The display of claim 6, wherein the first, second, and third light emitting sub-pixels form a color pixel.

10. A color display situated on a substrate surface, said color display comprising:
a first light emitting sub-pixel situated on said substrate surface and comprising a first base electrode, a first transparent electrode, and a first light-emissive layer interposed between said first base electrode and said first transparent electrode, said first light-emissive layer comprising fluorescent material and adapted to emit blue light;
a second light emitting sub-pixel situated on said substrate surface and comprising a second base electrode, a second transparent electrode, and a second light-emissive layer interposed between said second base electrode and said second transparent electrode, said second light-emissive layer comprising phosphorescent material and adapted to emit red light; and
a third light emitting sub-pixel situated on said substrate surface and comprising a third base electrode, a third transparent electrode, and a third light-emissive layer interposed between said third base electrode and said third transparent electrode, said third light-emissive layer comprising phosphorescent material and adapted to emit green light.

11. The color display of claim 10, wherein said second and third light emitting sub-pixels have a greater efficiency than said first light emitting sub-pixel.

12. The color display of claim 10, wherein said first light emitting sub-pixel, said second light emitting sub-pixel, and said third light emitting sub-pixel are arranged proximate to each other on said substrate surface.

13. The color display of claim 10, wherein said first light emitting sub-pixel, said second light emitting sub-pixel, and said third light emitting sub-pixel are arranged laterally adjacent to each other on said substrate surface.

14. A display situated on a substrate, said display comprising:
a first light emitting sub-pixel situated on said substrate surface and comprising a first base electrode, a first transparent electrode, and first and second light-emissive layers interposed between said first base electrode and said first transparent electrode, said first light emitting sub-pixel further comprising a first interlayer interposed between said first and second light-emissive layers, said first and second light-emissive layers each adapted to emit light of a first color; and
a second light emitting sub-pixel situated on said substrate surface and comprising a second base electrode, a second transparent electrode, and third and fourth light-emissive layers interposed between said second base electrode and said second transparent electrode, said second light emitting sub-pixel further comprising a second interlayer interposed between said third and fourth light-emissive layers, said third and fourth light-emissive layers each adapted to emit light of a second color, said second color being different than said first color.

15. The display of claim 14, wherein said second light emitting sub-pixel has a greater efficiency than said first light emitting sub-pixel.

16. The display of claim 14, wherein said first light emitting sub-pixel and said second light emitting sub-pixel are arranged proximate to each other on said substrate surface.

17. The display of claim 14, wherein said first light emitting sub-pixel and said second light emitting sub-pixel are arranged laterally adjacent to each other on said substrate surface.

18. The display of claim 14, wherein:
said first light-emissive layer is adapted to emit blue light; and
said second light-emissive layer is adapted to emit one of red light and green light.

19. The display of claim 14, further comprising:
a third light emitting sub-pixel situated on said substrate surface and comprising a third base electrode, a third transparent electrode, and fifth and sixth light-emissive layers interposed between said third base electrode and said third transparent electrode, said third light emitting sub-pixel further comprising a third interlayer interposed between said fifth and sixth light-emissive layers, said fifth and sixth light-emissive layers each adapted to emit light of a third color, said third color being different than said first color and said second color;
wherein said second light-emissive layer is adapted to emit red light; and
wherein said third light-emissive layer is adapted to emit green light.

20. The display of claim 14, wherein said first light emitting sub-pixel, said second light emitting sub-pixel, and said third light emitting sub-pixel are arranged proximate to each other on said substrate surface.

21. The display of claim 14, wherein said first light emitting sub-pixel, said second light emitting sub-pixel, and said third light emitting sub-pixel are arranged laterally adjacent to each other on said substrate surface.
